(19) United States
(12) Patent Application Publication
(10) Pub. No.: US 2025/0060671 A1
(43) Pub. Date: Feb. 20, 2025

(54) SUBSTRATE PROCESSING APPARATUS AND METHOD

(71) Applicant: ASM IP Holding B.V., Almere (NL)

(72) Inventors: Ivo Raaijmakers, Almere (NL); Daniele Piumi, Etterbeek (BE); Ivan Zyulkov, Brussels (BE); David Kurt de Roest, Kessel-Lo (BE); Michael Eugene Givens, Phoenix, AZ (US)

(21) Appl. No.: 18/936,501

(22) Filed: Nov. 4, 2024

Related U.S. Application Data
(63) Continuation of application No. 16/931,275, filed on Jul. 16, 2020, now Pat. No. 12,169,361.
(60) Provisional application No. 62/880,491, filed on Jul. 30, 2019.

(51) Int. Cl. G03F 7/16

(52) U.S. Cl. CPC G03F 7/162

(57) ABSTRACT

A substrate processing method and apparatus to create a sacrificial masking layer is disclosed. The layer is created by providing a first precursor selected to react with one of a radiation modified and unmodified layer portion and to not react with the other one of the radiation modified and unmodified layer portion on a substrate in a reaction chamber to selectively grow the sacrificial masking layer.

### CROSS-REFERENCE TO RELATED APPLICATIONS

This application is a continuation of, and claims priority to, U.S. patent application Ser. No. 16/931,275 filed Jul. 16, 2020 and titled SUBSTRATE PROCESSING APPARATUS AND METHOD, which claims priority to and the benefit of U.S. Provisional Patent application Ser. No. 62/880,491, filed Jul. 30, 2019 and titled SUBSTRATE PROCESSING APPARATUS AND METHOD, the disclosures of which are hereby incorporated by reference in their entirety.

### FIELD OF INVENTION

The present disclosure relates generally to a substrate processing apparatus and method to create a sacrificial masking layer.

The substrate processing apparatus to create a sacrificial masking layer on a substrate may comprise a litho input/output port to transfer substrates between the substrate processing apparatus and a lithographic projection apparatus.

The substrate processing method to create a sacrificial masking layer may comprise:
providing a substrate with a radiation modifiable layer to a lithographic projection apparatus for patterning, and
patterning the radiation modifiable layer of the substrate with exposure radiation of the lithographic projection apparatus to modify the radiation modifiable layer where it is exposed to radiation.

### BACKGROUND OF THE DISCLOSURE

Substrate processing apparatus (such as tracks or coaters) may be used to perform different process steps on the substrate before and/or after pattern formation in a resist layer on the substrate. For example, if contaminants are present on the substrate, they may be removed by a chemical treatment. The substrate may be heated to a temperature sufficient to drive off any moisture that may be present on the substrate. An adhesion promoter may be applied to promote adhesion of the resist on the substrate.

In a resist deposition device of a substrate processing apparatus, the substrate may be covered with the resist layer, for example, by spin coating a resist. A viscous, liquid solution of resist may be dispensed onto the substrate, and the substrate may be spun to produce a thin uniform layer. The resist-coated wafer may then be baked to evaporate resist solvent.

The substrate with the resist layer may be transferred from the substrate processing apparatus to a lithographic projection apparatus. In the lithographic projection apparatus the substrate with the resist layer may be exposed to a patterned radiation beam of (extreme) ultraviolet radiation. The exposure to radiation causes a chemical change in the resist layer patterning the layer.

For EUV lithography, the resist layer may be very thin. Such a thin layer may not be very etch resistant.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments a substrate processing apparatus to create a sacrificial masking layer on a substrate may be provided. The substrate processing apparatus may comprise a litho input/output port to transfer substrates between the substrate processing apparatus and a lithographic projection apparatus. The substrate processing apparatus may be provided with a selective deposition device to provide a first precursor selected to react with one of a radiation modified and an unmodified layer portion and not reacting with the other one of the radiation modified and unmodified layer portion in the reaction chamber to create the sacrificial masking layer. The apparatus may comprise a substrate handler to transfer substrates between the litho input/output port and the selective deposition device. The apparatus may comprise a control system operably connected to the substrate handler and the selective deposition device. The control system may be provided with a memory provided with a program when executed on the control system to control: the substrate handler to pick up a substrate from the litho input/output port and move it to the selective deposition device; and, the selective deposition device to provide the first precursor selected to react with one of the radiation modified and unmodified layer portions and not reacting with the other one of the radiation modified and unmodified layer portions in the reaction chamber to create the sacrificial masking layer.

In some embodiments, a substrate processing method to create a sacrificial masking layer is disclosed. The substrate processing method may comprise providing a substrate with a radiation modifiable layer to a lithographic projection apparatus for patterning. The substrate processing method may further comprise patterning the radiation modifiable layer of the substrate with exposure radiation of the lithographic projection apparatus to modify the radiation modifiable layer where it is exposed to radiation. The substrate may be moved from the lithographic projection apparatus to a reaction chamber of a selective deposition device. A first precursor selected to react with one of the modified and unmodified layer portions and not reacting with the other one of the modified and unmodified layer portions may be provided in the reaction chamber to create the sacrificial masking layer.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a substrate processing method in accordance with at least one embodiment of the disclosure.

FIG. 2 illustrates a substrate processing apparatus suitable for the substrate processing method of FIG. 1.

FIG. 3 illustrates a selective deposition device for the substrate processing apparatus of FIG. 2.

FIGS. 4 and 5 illustrate resistless patterning methods according to embodiments of the present disclosure. Throughout FIGS. 4 and 5, the following numbering is adhered to: 410 radiation modifiable layer; 411—radiation-modified layer portion; 412—unmodified layer portion; 420—underlayer; 430—substrate; 440—sacrificial masking layer; 450—recess.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. The illustrations presented herein are not meant to be actual views of any particular material, structure, or device, but are merely idealized representations that are used to describe embodiments of the disclosure.

As used herein, the term “substrate” may refer to any underlying material or materials that may be used, or upon which, a device, a circuit, or a film may be formed. Additionally, the term “modifiable layer” may refer to any material into which an additional species, such as atoms, molecules, or ions, may be introduced. The term “semiconductor device structure” may refer to any portion of a processed, or partially processed, semiconductor structure that is, includes, or defines at least a portion of an active or passive component of a semiconductor device to be formed on or in a semiconductor substrate. For example, semiconductor device structures may include, active and passive components of integrated circuits, such as, for example, transistors, memory elements, transducers, capacitors, resistors, conductive lines, conductive vias, and conductive contact pads.

As used herein, the term “precursor” can refer to a compound that participates in the chemical reaction that produces another compound, and particularly to a compound that constitutes a film matrix or a main skeleton of a film; the term “reactant” can be used interchangeably with the term precursor. A precursor can include material that is a gas at normal temperature and pressure (NTP), a vaporized solid and/or a vaporized liquid, and can be constituted by a single gas or a mixture of gases, depending on the context.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

A number of example materials may be given throughout the embodiments of the current disclosure, it should be noted that the chemical formulas given for each of the example materials should not be construed as limiting and that the non-limiting example materials given should not be limited by a given example stoichiometry.

One object of the present disclosure is to provide patterning devices and methods that avoid adhesion problems that might occur between photolithographic resist and underlying layers.

Another object of the present disclosure is to provide patterning devices and methods that avoid photo acid segregation to a resist/air interface.

Another object of the present disclosure is to provide patterning devices and methods that allow lithographic procedures that do not substantially suffer from scumming defects and/or resist line breaks.

Another object of the present disclosure is to provide patterning devices and methods that allow lithographic procedures that do not substantially suffer from pattern collapse.

Another object of the present disclosure is to provide patterning devices and methods that allow the deposition of lithographic layers having a high etch budget.

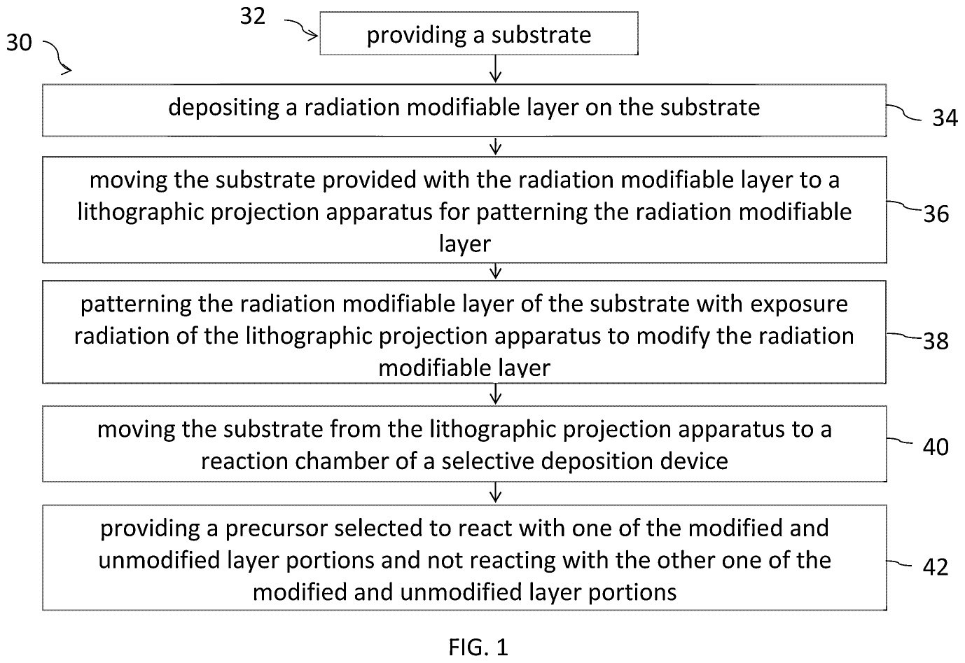

FIG. 1 illustrates an exemplary substrate processing method in accordance with at least one embodiment. The embodiment may include a substrate processing method to create a sacrificial masking layer.

The substrate processing method 30 may comprise: in step 32, providing a substrate, for example, to a modifiable layer deposition device; in step 34, depositing a radiation modifiable layer on the substrate in the modifiable layer deposition device; and in step 36, moving the substrate provided with the radiation modifiable layer to a lithographic projection apparatus for local modification, e.g., patterning. The substrate with the modifiable layer may also be obtained from somewhere else.

In fact the modifiable layer may also be the top surface of the substrate or a layer provided as the top surface. The high energy radiation of the EUV may alter the properties of the top surface which may create the selectivity for a selective deposition process to create the etch mask.

In some embodiments, the modifiable layer comprises carbon, and it may comprise chemical bonds selected from the list consisting of C≡C, C—N, and C—O bonds. Such bonds may be suitably broken by means of EUV radiation, thus locally modifying the properties of the modifiable layer in exposed areas. Such local modifications may then be leveraged for area-selective depositions.

In some embodiments, the radiation modifiable layer comprises one or more elements selected from the list consisting of Sn, Sb, Hf, In, and Te. Additionally or alternatively, an element selected from the list consisting of Sn, Sb, Hf, In, and Te may be provided in an underlayer on which the radiation modifiable layer is deposited. Thus, in some embodiments, a process for depositing the radiation modifiable layer involves depositing the radiation modifiable layer on an underlayer comprising an element selected from the list consisting of Sn, Sb, Hf, In, and Te. The underlayer may comprise, for example SiOC and/or SiOCN, and may be deposited methods which are known as such, e.g. methods employing PECVD or PEALD. Without the invention being bound to any theory or particular mode of operation, it is believed that these elements improve the sensitivity of the modifiable layer with respect to EUV radiations through their relatively high capture cross sections for EUV photons.

In the lithographic projection apparatus, the radiation modifiable layer of the substrate may be patterned with exposure radiation of the lithographic projection apparatus in step 38 to modify the radiation modifiable layer where it is exposed to radiation; and moving the substrate from the lithographic projection apparatus to a reaction chamber of a selective deposition device in step 40. In the selective deposition device, a first precursor selected to react with one of the modified and unmodified layer portions and not to react with the other one of the modified and unmodified layer portions may be provided in the reaction chamber to create the sacrificial masking layer in step 42.

Since the first precursor only reacts with one of the modified and unmodified layer portions and does not react with the other one of the modified and unmodified layer portions, the sacrificial masking layer may be created with an etch resistance that may be independent of the thickness of the radiation modifiable layer. The radiation modifiable layer provided in step 34 may have a thickness of one monolayer. The radiation modifiable layer may have a thickness of more than one monolayer. The radiation modifiable layer may have a thickness between 0.1 to 50 nm, or between 0.5 and 40 nm, more preferably a thickness of 5 to 20 nm. In some embodiments, the radiation modifiable layer may have a thickness of from at least 0.1 nm to at most 0.5 nm, or from at least 0.5 nm to at most 1.0 nm, or from at least 1.0 nm to at most 2.0 nm, or from at least 2.0 nm to at most 5.0 nm, or from at least 5.0 nm to at most 10.0 nm, or from at least 10.0 nm to at most 20.0 nm, or from at least 20.0 nm to at most 50.0 nm.

According to the disclosure there may be no need to remove some of the radiation modifiable layer with a special developer solution directly after patterning with exposure radiation of the lithographic projection apparatus. At very small feature sizes, there may be a risk of pattern collapse after removing a portion of the radiation modifiable layer. The risk of pattern collapse may increase by thicker radiation modifiable layers. By not removing the portion of the radiation modifiable layer with developer solution, the radiation modifiable layer may be better stabilized.

The first precursor may be selected to react with one of the modified and unmodified layer portions and to not to react with the other one of the modified and unmodified layer portions. The etch resistance may be changed by the first precursor reacting with one of the modified and unmodified layer portions and thereby a sacrificial masking layer may be created. The substrate may be etched through the sacrificial masking layer, whereby one of the modified and unmodified layer portions may be removed. After the etching, the sacrificial masking layer may be completely removed if it is not necessary anymore.

Thus, in some embodiments of the disclosure, the radiation modifiable layer may be used for forming a plurality of recesses in the substrate. In such embodiments, a sacrificial masking layer may be suitably deposited on any one of the radiation modified layer portion and the unmodified layer portion. The sacrificial masking layer may be deposited, for example, via plasma-enhanced atomic layer deposition (ALD), thermal ALD, radical-enhanced ALD (REALD), plasma-enhanced chemical vapor deposition (CVD), or thermal CVD.

In some embodiments, the sacrificial masking layer is deposited by means of a selective ALD process employing a precursor which is more reactive with respective to OH groups compared to CHₓ groups, with x being an integer from 1 to 3. Advantageously, the precursor used in such embodiments is not substantially reactive with respect to CHₓ groups, with x being an integer from 1 to 3, and it is highly reactive with respect to OH groups. Examples of processes employing precursors which may be more reactive with respect to OH groups than CH₃ groups include ALD of TiN or TiO₂ using TiCl₄ and NH₃ or H₂O TDMAT (tetrakis(dimethylamido)titanium) and H₂O, and/or TTIP (titanium tetraisopropoxide) and H₂O. Another example of a process that employs precursors which may be more reactive with respect to OH groups includes ALD of Ru by means of EBECHRu (ethyl-benzene ethyl-1,4-cyclohexadiene ruthenium) Without the invention being limited to any specific theory or mode of operation, it is believed that these processes exhibit nucleation delay on CH₃ terminated surfaces with respect to OH terminated surfaces, which may be leveraged to provide selective growth on OH terminated surfaces versus CH₃ terminated surfaces.

In some embodiments, the sacrificial masking layer is deposited by means of a selective ALD process employing a precursor which is less reactive with respective to OH groups compared to CHₓ groups, with x being an integer from 1 to 3. Advantageously, the precursor used in such embodiments is highly reactive with respect to CHₓ groups, with x being an integer from 1 to 3, and it is less reactive or non-reactive with respect to OH groups. Such a process may be used for selective deposition of a sacrificial masking layer on a CHₓ terminated surface versus an OH terminated surface. For example, the precursor may comprise ruthenium tetroxide and H₂ may be used as a reagent. Thus a ruthenium-containing sacrificial masking layer may be selectively deposited by e.g. thermal ALD or plasma-enhanced ALD on a CHₓ terminated surface versus an OH terminated surface.

After the sacrificial masking layer has been deposited, the substrate may be subjected to an etch step. Suitable etch steps as such are known in the art. The sacrificial masking layer may be removed after the etch step, if desirable, using techniques which are known as such.

Optionally, the sacrificial masking layer deposition step and the etching step may be performed in one and the same reaction chamber. Optionally, any sacrificial masking layer removal step may be performed in the same reaction chamber as well.

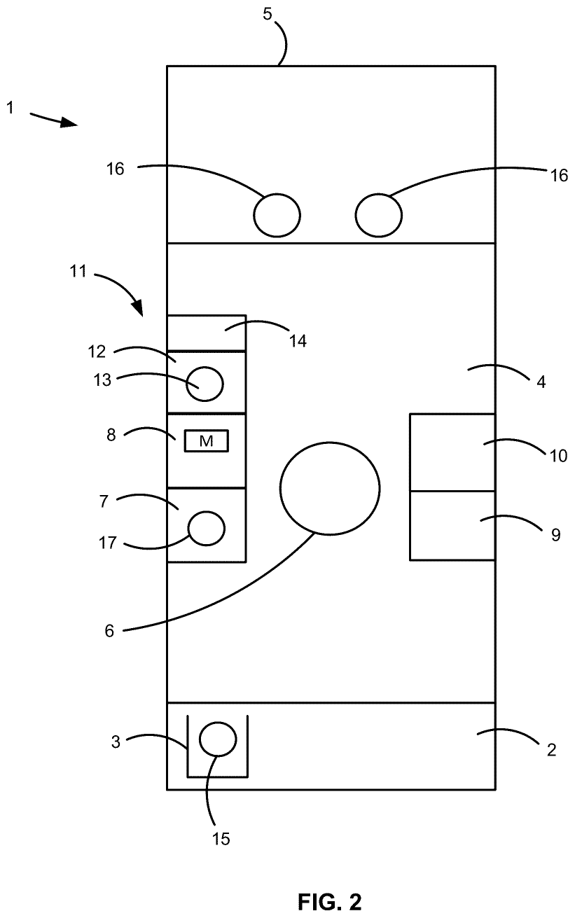

A non-limiting example of a substrate processing apparatus of the disclosure may be illustrated in FIG. 2, which comprises a schematic diagram of an exemplary substrate processing apparatus 1 according to an embodiments of the disclosure. It should be noted that the substrate processing apparatus 1 illustrated in FIG. 2 is a simplified schematic version of the exemplary substrate processing apparatus and does not contain each and every element, i.e., such as each and every valve, gas line, heating element, and reactor component, etc., that may be utilized in the fabrication of the substrate processing apparatus of the current disclosure.

The exemplary substrate processing apparatus 1 may comprise a cassette handling portion 2 on which cassettes 3 with a plurality of substrates 15 may be placed. The cassette handling portion 2 may function as a fab input/output port to transfer substrates 15 between the substrate processing apparatus and the rest of the fab in cassettes 3. The substrate processing apparatus 1 may be suitable for the substrate processing method of FIG. 1.

The substrate processing apparatus may have a litho input/output port 5. Substrates may be transferred to a lithographic projection apparatus via the litho input/output port 5.

The substrate processing apparatus may have a processing portion 4. In the processing portion 4 a modifiable layer deposition device 7 for depositing a radiation modifiable layer on a substrate may be provided.

The modifiable layer deposition device 7 may comprise a radiation modifiable coating device for coating a radiation modifiable material (e.g., resist) on the substrate. The modifiable layer deposition device 7 may comprise a rotatable substrate table 17 for rotating the substrate and a liquid dispenser for providing a liquid to the surface of the substrate. Radiation modifiable material (e.g., resist) in liquid form may be provided to the substrate while it may be spun at 10 to 100 revolutions per second for 20 to 60 seconds.

In the processing portion 4 a substrate handler 6 to transfer substrates between the cassettes 3 at the cassette handling portion 2, the modifiable layer deposition device 7 and the litho input/output port 5 may be provided. The substrate handler 6 may have a substrate holder that is moveable in the horizontal and vertical direction for this purpose.

In the processing portion 4, a selective deposition device 11 provided with a reaction camber 12 and a substrate table 13 to hold a substrate in the reaction chamber 12 may be provided. A first precursor selected to react with one of a radiation modified and an unmodified layer portions and not reacting with the other one of the radiation modified and unmodified layer portions may be provided in the reaction chamber to create the masking layer. The selective deposition device may comprise a precursor distribution and removal system 14 comprising one or more reaction chamber valves to provide to and remove from the reaction chamber 12 a gaseous first precursor. The substrate handler 6 may be constructed and arranged for moving the substrate to and from the selective deposition device 11 as well.

The substrate processing apparatus 1 may be provided with a control system 8 operably connected to the substrate handler 6, the radiation modifiable layer deposition device 7 and the selective deposition device 11 and provided with a memory M provided with a program. When the program in the memory M is executed on the control system 8 it may control:
the substrate handler 6 to pick up a substrate 15 from a cassette 3 at the cassette handling portion 2 and to move the substrate to the modifiable layer deposition device 7 and position it on the rotatable substrate table 17;
the radiation modifiable layer deposition device 7 to deposit a radiation modifiable layer on the substrate on the rotatable substrate table 17; and,
the substrate handler 6 to pick up the substrate from the rotatable substrate table 17 and to move the substrate to a lithographic projection apparatus via the litho input/output port 5, for example, via the first and second substrate tables 16 at the litho input/output port 5. After locally modifying the radiation modifiable layer with exposure radiation in the lithographic projection apparatus, the substrate may be transferred back to the substrate processing apparatus via the litho input/output port 5.

The program in the memory M of the controller 8 may be executed to control: the substrate handler 6 to pick up the substrate through the litho input/output 5 and to move the substrate to the selective deposition device 11; and,
the selective deposition device 11 to provide the first precursor selected to react with one of the radiation modified and unmodified layer portions and not reacting with the other one of the radiation modified and unmodified layer portions in the reaction chamber with the precursor distribution and removal system 14 to create the sacrificial masking layer; and,
the substrate handler 6 to pick up the substrate from the selective deposition device 11 and to move it to the fab input/output port 2.

Heating station 9 and cooling station 10 may be provided in the processing portion 4 for respectively baking and cooling of the substrate. Heating station 9 and cooling station 10 may be supplied with substrates by the substrate handler 6 as well. Heating and/or cooling may be required before transferring the substrates to the lithographic projection apparatus.

The modifiable layer deposition device 7 may be omitted when, for example, the substrate with the radiation modifiable layer is obtained from elsewhere. In such case, the substrate handler may not need to move the substrate to the modifiable layer deposition device and from the modifiable layer deposition device move the substrate to a lithographic projection apparatus via the litho input/output port.

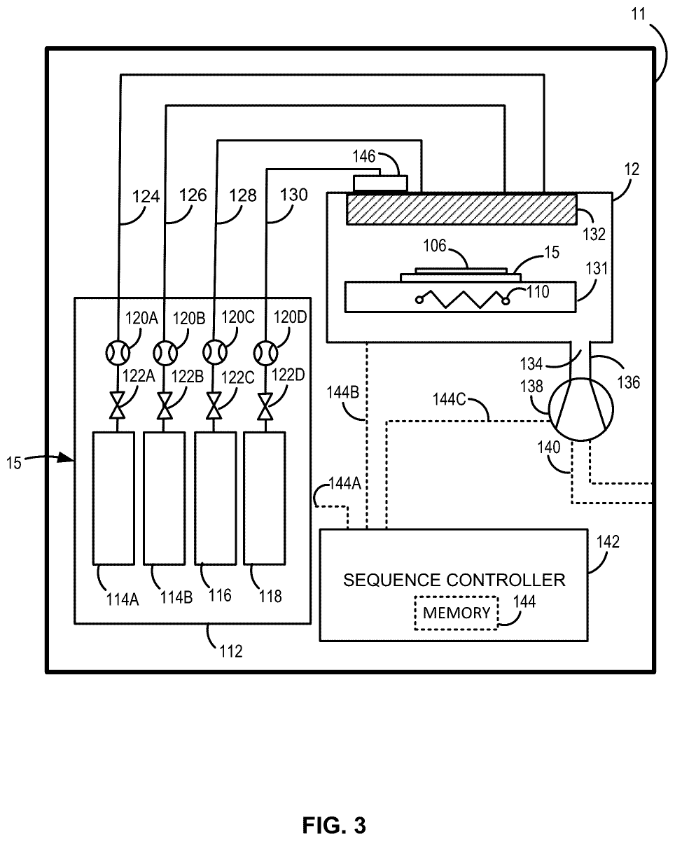

FIG. 3 illustrates a non-limiting exemplary selective deposition device 11 for the substrate processing apparatus 1 of FIG. 2. The selective deposition device 11 may comprise a reaction chamber 12 constructed and arranged to hold at least a substrate 15 provided with a radiation modifiable layer 106 thereon.

Reaction chambers 12 capable of being used to selectively deposit with a (first) precursor may include reaction chambers configured for atomic layer deposition (ALD) processes, or plasma enhanced atomic layer deposition (PEALD), or radical-enhanced atomic layer deposition (REALD) as well as reaction chambers configured for chemical vapor deposition (CVD), plasma enhanced chemical vapor deposition (PECVD), or metal organic CVD (MOCVD) processes. Reaction chamber 12 may also be either capable of in-situ directional plasma etch or being connected to a reaction chamber 12b, designed for plasma etch capability. According to some embodiments, a showerhead reaction chamber may be used. According to some embodiments, cross-flow, batch, minibatch, soaking or spatial ALD reaction chambers may be used.

In some embodiments of the disclosure, a batch reaction chamber may be used. In some embodiments, a vertical batch reaction chamber may be used. In other embodiments, a batch reaction chamber comprises a minibatch reactor configured to accommodate 10 or fewer wafers, 8 or fewer wafers, 6 or fewer wafers, 4 or fewer wafers, or 2 or fewer wafers.

Disposed within the reaction chamber 12 may be a substrate holder 13 with at least one substrate 15 with a radiation modifiable layer 106 disposed thereon, i.e., disposed on an upper surface of the substrate 15. In some embodiments of the disclosure, the substrate 15 may comprise a planar substrate or a patterned substrate.

In some embodiments, the formation of a radiation modifiable layer comprises the deposition of an underlayer, e.g. an amorphous carbon (sp3/sp2 carbon) underlayer, on a substrate. An amorphous carbon underlayer may be deposited, for example, by means of hydrocarbon-containing precursor and a plasma such as a noble gas plasma, e.g. a helium plasma or an argon plasma. A radiation modifiable layer may be formed on the surface of the underlayer by means of a further plasma treatment. In some embodiments, the radiation modifiable layer comprises surface functional groups on the amorphous carbon underlayer, such as NH₂, Cl, F, and CH₃ functional groups. In exemplary embodiments, such groups can be formed on the surface of the amorphous carbon underlayer by subjecting the underlayer to a plasma treatment wherein a plasma is used that comprises F, Cl, N, and/or H. The thusly formed NH₂, Cl, F, and/or CH₃ functional groups may be damaged upon exposure to extreme ultraviolet (EUV) radiation due to scission of C—NH₂, C═Cl, C—F, and/or C═CH₃ bonds, and may then be replaced by C—OH groups when the wafer is exposed to oxygen. The oxygen may be provided e.g. by exposure in a reactor chamber, or by exposing the substrate to atmospheric air.
(i) In some embodiments, the formation of a radiation modifiable layer comprises the deposition of a self-assembled monolayer (SAM). In this case, EUV radiation may be used to remove one or more functional groups from the SAM, thereby modifying the radiation modifiable layer. Exemplary functional groups that may be removed by means of EUV radiation include NH₂, Cl, F, I, Br, and CH₃. Removing one or more of these functional groups may drastically alter the surface properties of exposed areas of a SAM-coated substrate. In some embodiments, the SAM may be deposited by means of CVD in soaking mode, i.e. by exposing the substrate to SAM vapor until SAM adsorption on the substrate reaches saturation. Alternatively, the SAM may be deposited by means of a plurality of SAM precursor pulses. This may improve SAM layer densification. The pulses may last, e.g., from 0.1 to 1.0 s, or from 1.0 to 2.0 s, or from 2.0 to 5.0 s, or from 5.0 to 10.0 s, or from 10.0 to 20.0 s.

In some embodiments, the radiation modifiable layer comprises a polymer film. Such a polymer film may be deposited, for example, by means of molecular layer deposition. Suitable films include polyimide, polyamide, and polyurea films. Exemplary polymer films may be deposited by means of the methods disclosed in U.S. patent Ser. No. 10/343,186B2, which is hereby incorporated by reference in its entirety.

The substrate 15 may comprise one or more materials including, but not limited to, silicon (Si), germanium (Ge), germanium tin (GeSn), silicon germanium (SiGe), silicon germanium tin (SiGeSn), silicon carbide (SiC), or a group III-V semiconductor material, such as, for example, gallium arsenide (GaAs), gallium phosphide (GaP), or gallium nitride (GaN). In some embodiments of the disclosure, the substrate 15 may comprise an engineered substrate wherein a surface semiconductor layer is disposed over a bulk support with an intervening buried oxide (BOX) disposed there between.

Patterned substrates may comprise substrates that may include semiconductor device structures formed into or onto a surface of the substrate, for example, a patterned substrate may comprise partially fabricated semiconductor device structures, such as, for example, transistors and/or memory elements. In some embodiments, the substrate may contain monocrystalline surfaces and/or one or more secondary surfaces that may comprise a non-monocrystalline surface, such as a polycrystalline surface and/or an amorphous surface. Monocrystalline surfaces may comprise, for example, one or more of silicon (Si), silicon germanium (SiGe), germanium tin (GeSn), or germanium (Ge). Polycrystalline or amorphous surfaces may include dielectric materials, such as oxides, oxynitrides or nitrides, such as, for example, silicon oxides and silicon nitrides.

In some embodiments of the disclosure, the substrate 15 has a radiation modifiable layer 106 disposed thereon, i.e., disposed on an upper surface of the substrate 15. The radiation modifiable layer 106 may comprise any material which after exposure to radiation may selectively react with a (first) precursor to grow a masking layer selectively on the radiation modifiable layer 106.

In some embodiments of the disclosure the radiation modifiable layer 106 may comprise at least one of a polymer resist, such as, for example, a photoresist, an extreme ultraviolet (EUV) resist, an immersion photoresist, a chemically amplified resist (CAR), or an electron beam resist (e.g., poly(methyl methacrylate) (PMMA)). The radiation modifiable layer 106 also may be a metal, an oxide, a self-assembled monolayer (SAM) or any other material. Additionally or alternatively, the radiation modifiable layer 106 may comprise C, N, H, and/or O. Optionally, the radiation modifiable layer comprises C—F bonds, C═Cl bonds, and/or C—NH₂ bonds. These bonds may be broken by means of irradiation with EUV photons, thereby resulting in locally changed layer properties, which may influence dry and/or wet etch rate. Additionally or alternatively, it may allow selective deposition on exposed areas versus non-exposed areas, e.g. area-selective sacrificial masking layer deposition.

In some embodiments, the radiation modifiable layer further comprises one or more elements selected from the list consisting of Sn, Sb, Hf, In, and Te. Additionally or alternatively, an element selected from the list consisting of Sn, Sb, Hf, In, and Te may be provided in an underlayer on which the radiation modifiable layer is deposited. Thus, in some embodiments, a process for depositing the radiation modifiable layer involves depositing the radiation modifiable layer on an underlayer comprising an element selected from the list consisting of Sn, Sb, Hf, In, and Te. Without the invention being bound to any theory or particular mode of operation, it is believed that these elements may improve the sensitivity of the modifiable layer with respect to EUV radiation through their relatively high capture cross sections for EUV photons.

In some embodiments of the disclosure the radiation modifiable layer 106 may comprise a porous material, e.g., micro-porous and/or nano-porous, including porous materials such as, for example, spin-on-glasses (SOG), and spin-on-carbon (SOC). In some embodiments of the disclosure, the radiation modifiable layer 106 may be provided with one or more sacrificial masking layer materials, including, but not limited to, boron carbides, amorphous carbon, silicon oxides, silicon nitrides, and silicon oxynitrides.

In some embodiments of the disclosure, the radiation modifiable layer 106 may comprise a patterned radiation modifiable material such as a patterned resist or patterned sacrificial masking layer which comprises one or more features. The features may be transferred during a subsequent etching process into the underlying substrate. The features may comprise any geometry that may be formed depending on the exposure and associated development processes and may include, but is not limited to, line features, block features, open pore features, and circular features.

In some embodiments of the disclosure, the radiation modifiable layer 106 may comprise a flat radiation modifiable material which, after local modification, may be patterned during a subsequent process. For example, the radiation modifiable layer 106 may comprise flat resist which may be patterned during a subsequent lithographic exposure step or the radiation modifiable layer 106.

The substrate 15 may be disposed in the reaction chamber 12 and held in position by the substrate holder 13 configured to retain at least one substrate thereon. In some embodiments of the disclosure, the selective deposition processes disclosed herein may utilize processes which heat the substrate 15 and the associated radiation modifiable layer 106 to a suitable process temperature. Therefore, the substrate holder 13 may comprise one or more heating elements 110 which may be configured to heat the substrate 15 with the radiation modifiable layer 106 disposed thereon.

The heating elements 110 may be configured to heat the substrate 15 to a temperature between 2° and 450° C., preferably between 5° and 150° C., more preferably between 6° and 120° C. and most preferably between 7° and 100° C., for example, 85° C. In some embodiments of the disclosure, the selective deposition device 11 is constructed and arranged to control the pressure in the reaction chamber to value between 0.001 and 1000, preferably 0.1 to 500 and most preferably 1 to 100 Torr.

In some embodiments of the disclosure, the selective deposition device 11 may comprise a precursor distribution and removal system 14. The precursor distribution and removal system may comprise a gas delivery system 112 which may further comprise one or more precursor sources 114A and 114B constructed and arranged to provide a vapor of a number of precursors and dispense the associated vapors to the reaction chamber 12. The gas delivery system 112 may also comprise a source vessel 116 configured for storing and dispensing a purge gas that may be utilized in a purge cycle of the exemplary selective deposition processes described herein. The gas delivery system 112 may also comprise a reactant source vessel 118 configured for containing and dispensing a precursor to the reaction chamber 12 to be utilized in an exemplary selective deposition process described herein. As a non-limiting example, the selective deposition device 11 may include a first precursor source 114A constructed and arranged to provide a vapor of a first precursor. In some embodiments, the first precursor source 114A may comprise a first precursor evaporator constructed and arranged to evaporate a first precursor.

In some embodiments, the first precursor source 114A may comprise a source vessel configured for storing and containing a first precursor under suitable operating conditions. For example, the first precursor may comprise a solid precursor, a liquid precursor, or a vapor phase precursor, and the source vessel may be configured for storing and containing the solid, liquid, or vapor phase precursor under suitable operating conditions.

In some embodiments, the first precursor source may comprise a first precursor evaporator which may include one or more controllable heating elements which may heat the first precursor to a suitable operating temperature to thereby controllably evaporate a portion of the first precursor, the evaporated vapor subsequently being distributed to the reaction chamber 12 via suitable means to selectively deposit on the radiation modifiable layer. In some embodiments, the one or more heating elements associated with the first precursor source 114A may be configured to control the vapor pressure of the first precursor. In addition, a flow controller 120A, such as, for example, a mass flow controller (MFC), may be further associated with the first precursor source 114A and may be configured to control the mass flow of the vapor produced from the first precursor source 114A, such as, for example, the first precursor evaporator. In addition to the flow controller 120A, a valve 122A, e.g., a shut-off valve, may be associated with the first precursor source 114A and may be utilized to disengage the first precursor source 114A from the reaction chamber 12, i.e., when the valve 122A is in the closed position, vapor produced by the first precursor source 114A may be prevented from flowing into the reaction chamber 12.

In additional embodiments, the first precursor source 114A may further comprise a carrier gas input (not shown) such that a carrier gas (e.g., nitrogen) may be passed over or bubbled through the first precursor such that the first precursor may become entrained in the carrier gas and the carrier gas/first precursor vapor may be subsequently delivered to the reaction chamber 12 by appropriate means.

In some embodiments of the disclosure, the selective deposition device 11 (FIG. 3) may comprise a precursor distribution and removal system 14 constructed and arranged to provide the reaction chamber 12 with a vapor of the first precursor from the first precursor source 114A and to remove the vapor of the first precursor from the reaction chamber 12.

In some embodiments of the disclosure, the selective deposition device 11 may comprise a precursor distribution and removal system 14 constructed and arranged to provide the reaction chamber 12 with a vapor of the first precursor from the first precursor source 114A including an element such as a metal or a semiconductor, e.g. a group IV semiconductor. The element such as a metal or a semiconductor may be selected from a group comprising Aluminium (Al), Hafnium (Hf), Gallium (Ga), Germanium (Ge), Silicon (Si), Zirconium (Zr), Indium (In), Lithium (Li), Tellurium (Te), Antimony (Sb), Titanium (Ti), Tantalum (Ta) and Tin (Sn) in the reaction chamber 12.

In some embodiments of the disclosure, the selective deposition device 11 may comprise a precursor distribution and removal system 14 constructed and arranged to provide a precursor comprising an alkylamide precursor, e.g. a Metal Alkylamide precursor or a group IV semiconductor alkylamide precursor, in the reaction chamber 12.

In some embodiments of the disclosure, the selective deposition device 11 may comprise a precursor distribution and removal system 14 constructed and arranged to provide a precursor selected from the group comprising trimethyl aluminum (TMA), triethylaluminum (TEA), and dimethylaluminumhydride (DMAH). The selective deposition device may thereby selectively provide a metal such as an aluminum in or on one of the modified and unmodified layer portions such as, for example, a resist.

In some embodiments of the disclosure, the selective deposition device 11 may comprise a precursor distribution and removal system 14 constructed and arranged to provide the reaction chamber 12 with a vapor of the first precursor from the first precursor source 114 comprising a metal halide or a halide of a group IV semiconductor in the reaction chamber 12.

In some embodiments of the disclosure, the precursor distribution and removal system 14 of selective deposition device 11 is constructed and arranged to provide a precursor comprising SnI4 or SnCl4 in the reaction chamber. In some embodiments of the disclosure, the exemplary selective deposition device 11 may comprise a precursor distribution and removal system constructed and arranged to provide a precursor selected from the group comprising Tetraethyltin, Tetramethyltin or Tinacetylacetonate in the reaction chamber. The selective deposition device 11 may thereby selectively provide a metal such as a tin in or on one of the modified and unmodified layer portions such as, for example, a resist.

In some embodiments of the disclosure, the exemplary selective deposition device 11 may comprise a precursor distribution and removal system 14 constructed and arranged to provide the reaction chamber 12 with a vapor of the first precursor from the first precursor source 114 comprising a metal or a group IV semiconductor, for example Magnesium and/or Calcium in the reaction chamber.

In some embodiments, the selective deposition device 11 may be constructed and arranged to selectively deposit silicon in or on one of the modified and unmodified layer portions such as, for example, a resist.

In some embodiments, the first precursor source 114A may be constructed and arranged to provide a vapor of an aminosilane.

In more detail, the precursor distribution system may comprise gas delivery system 112, and one or more gas lines, such as, for example, gas line 124 in fluid communication with first precursor source 114A, gas line 126 in fluid communication with second precursor source 114B, gas line 128 in fluid communication with source vessel 116, and gas line 130 in fluid communication with reactant source vessel 118. As a non-limiting example, gas line 124 is fluidly connected to the first precursor source 114A and may be configured for conveying a vapor of the first precursor to the reaction chamber 12.

The precursor distribution system may further comprise a gas dispenser 132 configured for dispensing the vapor of the first precursor into reaction chamber 12 and over the substrate 15 with the radiation modifiable layer 106 disposed thereon, the gas dispenser 132 being in fluid communication with gas line 124, in addition to being in fluid communication with gas lines 126, 128, and 130.

As a non-limiting example embodiment, the gas dispenser 132 may comprise a showerhead as illustrated in block form in FIG. 3. It should be noted that although the showerhead is illustrated in block form, the showerhead may be a relatively complex structure. In alternative embodiments, the showerhead may be configured to maintain separation between multiple vapors introduced into the showerhead, the multiple vapors only coming into contact with one another in the vicinity of the substrate 15 disposed within the reaction chamber 12. Further, the showerhead may be configured to provide vertical or horizontal flow of gas into the reaction chamber 12. An exemplary gas distributor is described in U.S. Pat. No. 8,152,922, the contents of which are hereby incorporated herein by reference, to the extent such contents do not conflict with the present disclosure.

As illustrated in FIG. 3, the precursor distribution system may comprise gas delivery system 112, at least gas lines 124, 126, 128 and 130, and a gas distributor 132, however it should be noted that the precursor distribution system may include additional components not illustrated in FIG. 3, such as, for example, additional gas lines, valves, actuators, seals, and heating elements.

In addition to the precursor distribution system, the precursor distribution and removal system 14 of the selective deposition device 11 may also comprise a removal system constructed and arranged to remove gasses from the reaction chamber 12. In some embodiments, the removal system may comprise an exhaust port 134 disposed within a wall of reaction chamber 12, an exhaust line 136 in fluid communication with exhaust port 134, and a vacuum pump 138 in fluid communication with the exhaust line 136 and configured for evacuating gasses from within reaction chamber 12. Once the gas or gasses have been exhausted from the reaction chamber 12 utilizing vacuum pump 138 they may be conveyed along additional exhaust line 140 and exit the additional station 11 where they may undergo further abatement processes.

To further assist in the removal of precursor gasses, i.e., reactive vapors, from within reaction chamber 12, the removal system may further comprise a source vessel 116 fluidly connected through a gas line 128 to a gas distributor 132. For example, the source vessel 116 may be configured for containing and storing a purge gas, such as, for example, argon (Ar), nitrogen (N₂), or helium (He). A flow controller 120C and valve 122C associated with the source vessel 116 may control the flow and particularly the mass flow of purge gas conveyed through gas line 128 to gas distributor 132 and into reaction chamber 12 wherein the purge gas may assist in the removal of vapor phase precursor gases, inert gasses, and byproducts from within reaction chamber 12 and particularly purge precursor gas and unreacted byproducts from an exposed surface of modifiable layer 106. The purge gas (and any associated precursor and byproducts) may exit the reaction chamber 12 via exhaust port 134 through the utilization of vacuum pump 138.

In some embodiments of the disclosure, the selective deposition device 11 may further comprise, a sequence controller 142 operably connected to the precursor distribution system and the removal system and comprising a memory 144 provided with a program to execute selective deposition on or in one of the radiation modified and unmodified layer when run on the sequence controller.

### Sequence Controller

In more detail, the exemplary the selective deposition device 11 may comprise a sequence controller 142 which may also comprise control lines 144A, 144B, and 144C, wherein the control lines may interface various systems and/or components of the selective deposition device 11 to the sequence controller 142. For example, control line 144A may interface the sequence controller 142 with gas delivery system 112 and thereby provide control to the precursor distribution system including gas lines 124, 126, 128 and 130, as well as gas distributor 132. The control line 144B may interface the sequence controller 142 with the reaction chamber 12 thereby providing control over operation of the reaction chamber, including, but not limited to, process pressure and substrate table 13 temperature. The control line 144C may interface the sequence controller 142 with the vacuum pump 138 such that operation and control over the gas removal system may be provided by sequence controller 142. The sequence controller 142 may be operable connected to the control system 8 (in FIG. 2).

It should be noted that as illustrated in FIG. 3 the sequence controller 142 includes three control lines 144A, 144B, and 144C; however, it should be appreciated a multitude of control lines, i.e., electrically and/or optically connected control lines, may be utilized to interface the desired systems and components comprising the selective deposition device 11 with the sequence controller 142 thereby providing overall control over the device.

In some embodiments of the disclosure, the sequence controller 142 may comprise electronic circuitry to selectively operate valves, heaters, flow controllers, manifolds, pumps and other equipment included in the exemplary the selective deposition device 11. Such circuitry and components operate to introduce precursor gasses and purge gasses from respective precursor sources 114A, 114B, reactant source vessel 118 and purge gas source vessel 116. The sequence controller 142 may also control the timing of precursor pulse sequences, temperature of the substrate and reaction chamber 12, and the pressure of the reaction chamber and various other operations necessary to provide proper operation of the selective deposition device 11. In some embodiments, the sequence controller 142 may also comprise control software and electrically or pneumatically controlled valves to control the flow of precursors and purge gasses into and out of the reaction chamber 12. In some embodiments of the disclosure, the sequence controller 142 may comprise a memory 144 provided with a program to execute selective deposition on or in the radiation modifiable layer when run on the sequence controller. For example, the sequence controller 142 may include modules such as software or hardware components, such as, for example, a FPGA or ASIC, which performs certain selective deposition processes. A module can be configured to reside on an addressable storage medium of the sequence controller 142 and may be configured to execute one or more selective deposition processes.

In some embodiments of the disclosure, the memory 144 of sequence controller 142 may be provided with a program to execute providing a precursor selected to react with one of the modified and unmodified layer portions and not reacting with the other one of the modified and unmodified layer portions in the reaction chamber to create the sacrificial masking layer by: activating the precursor distribution system and removal system to provide the vapor of the precursor to the radiation modifiable layer 106 on the substrate 15 within the reaction chamber 12 whereby the precursor selectively reacts with one of the modified and unmodified layer portions of the radiation modifiable layer 106 on the substrate 15.

In some embodiments of the disclosure, the exemplary selective deposition device 11 may comprise a second precursor source 114B, such as, for example, a second precursor evaporator. In more detail, the second precursor source 114B may be constructed and arranged to provide a vapor of a second precursor. For example, the second precursor source 114B may comprise a second precursor evaporator that may be constructed and arranged to evaporate a second precursor. In some embodiments, the second precursor source 114B may be identical, or substantially identical, to the first precursor source 114A and therefore details regarding the second precursor source 114B are omitted for brevity.

In some embodiments, the precursor distribution system and removal system 14 may be constructed and arranged to provide the reaction chamber 12 with a vapor of the second precursor from the second precursor source 114B. For example, gas line 126 may be fluidly connected to the second precursor source 114B via flow controller 120B and valve 122B, and may convey the vapor of the second precursor from the second precursor source 114B to gas distributor 132 and subsequently into the reaction chamber 12. In some embodiments, the program in the memory 144 may be programmed to execute selective deposition on or in the radiation modifiable layer 106 when run on the sequence controller 142 by: activating the precursor distribution system and the removal system to provide the vapor of the second precursor to the reaction chamber 12 whereby the second precursor may react with one of the modified and unmodified layer portions 106 and not react with the other one of the modified and unmodified layer portions in the reaction chamber to create the sacrificial masking layer on the substrate 15.

In some embodiments of the disclosure, the program in the memory 144 may be programmed to execute selective deposition on radiation modifiable layer 106 when run on the sequence controller 142 by: activating the precursor distribution system and removal system to provide the second precursor after the first precursor, i.e., the first precursor source 114A may provide a vapor of the first precursor into the reaction chamber 12 and selectively deposit the material on or in the radiation modifiable layer 106 with the first precursor and subsequently the second precursor source 114B may provide a vapor of the second precursor to the reaction chamber 12 and selective deposition on or in radiation modifiable layer 106 with the second precursor. The selective deposition cycle of the program stored in the memory 144 may have the first period of providing the vapor of the first precursor longer than the third period of providing the vapor of the second precursor to execute selective deposition on or in the radiation modifiable layer 106 when run on the sequence controller 142.

In some embodiment, the sequence controller 142 may run a program on the memory 144 in order to activate the precursor distribution system and the removal system to provide the first precursor after the second precursor, i.e., the second precursor source 114B may provide a vapor of the second precursor to the reaction chamber 12 to selectively deposit on radiation modifiable layer 106 and subsequently the first precursor source 114A may provide a vapor of the first precursor to the reaction chamber 12 to selective deposit on the modifiable layer 106 with the first precursor vapor.

In some embodiments of the disclosure, the program stored in the memory 144 may be programmed to execute selective deposition on the radiation modifiable layer 106 when run on the sequence controller 142 by: activating the precursor distribution system and removal system to provide the first precursor to the reaction chamber 12, followed by a purge cycle to remove excess first precursor and any byproducts from the reaction chamber, and subsequently provide the second precursor to the reaction chamber, followed by a second purge cycle to remove excess second precursor and any byproducts from the reaction chamber.

In more detail, a program within the memory 144 of sequence controller 142 may first activate the first precursor source 114A and provide a vapor of the first precursor to the reaction chamber 12 to selectively deposit on or in the radiation modifiable layer 106, subsequently the first precursor source 114A may be deactivated and the fluid connection to the reaction chamber 12 between the first precursor source 114A and the reaction chamber 12 may disengaged, e.g., by the valve 122A associated with the first precursor source 114A. Once the first precursor source 114A is deactivated and disengaged from the reaction chamber 12 the program mounted in the memory 144 of sequence controller 142 may engage, or continue to engage, the vacuum pump 138 to exhaust excess vapor of the first precursor and any byproducts from the reaction chamber 12. In additional embodiments, in addition to utilizing the vacuum pump 138 to exhaust excess vapor of the first precursor and any byproducts from the reaction chamber 12, the program mounted in memory 144 of sequence controller 142 may activate source vessel 116 containing a source of purge gas, e.g., by opening the valve 122C associated the source vessel 116. The purge gas may flow through gas line 128 and into reaction chamber 12 via gas distributor 132 and purge the reaction chamber 12 and in particularly may purge the modifiable layer 106 disposed upon substrate 15. The program mounted in memory 144 of sequence controller 142 may subsequently deactivate the flow of purge gas through the reaction chamber 12 and subsequently activate the second precursor source 114B to thereby provide a vapor of the second precursor to the reaction chamber 12 and particular to selectively deposit on the radiation modifiable layer 106 with the second precursor vapor provided by the second vapor source 114B. The program mounted in memory 144 of sequence controller 142 may subsequently deactivate the flow of the vapor of the second precursor to the reaction chamber 12 and subsequently activate the source vessel 116 to again purge the reaction chamber, e.g., remove excess vapor of the second precursor.

In some embodiments of the disclosure, the program saved in the memory 144 may be programmed to execute selective deposition on or in the radiation modifiable layer 106 when run on the sequence controller 142 by: activating the precursor distribution system and removal system to provide the vapor of the second precursor to the reaction chamber, followed by a purge cycle to remove excess vapor of the second precursor and any byproducts from the reaction chamber, subsequently provide the vapor of the first precursor to the reaction chamber, followed by a purge cycle to remove excess vapor of the first precursor and any byproducts from the reaction chamber.

In additional embodiments of the disclosure, in addition to the first precursor source 114A and the second precursor source 114B, the exemplary additional station 11 may further comprise a reactant source vessel 118 and a reactant supply line, i.e., gas line 130, constructed and arranged to provide a reactant comprising an oxygen precursor to the reaction chamber 12.

In some embodiments of the disclosure, reactant source vessel 118 may comprise a reactant in the solid phase, in the liquid phase, or in the vapor phase. In some embodiments, the reactant source vessel 118 may comprise a reactant evaporator, i.e., one or more heating elements may be associated with the reactant source vessel to enable evaporation of the reactant and thereby provide a vaporized reactant comprising an oxygen precursor to the reaction chamber 12.

In some embodiments, the control of the flow of the vapor reactant comprising an oxygen precursor to the reaction chamber may be achieved through the use of the valve 122D and flow controller 120D both associated with the reactant source vessel 118. In some embodiments of the disclosure wherein the reactant source vessel 118 further comprises a reactant evaporator, the reactant evaporator may be constructed and arranged to evaporate at least one of water (H₂O), or hydrogen peroxide (H₂O₂) as the reactant comprising an oxygen precursor.

In some embodiments of the disclosure, the reactant source vessel 118 may store and dispense a gaseous oxygen precursor to the reaction chamber 12 via reactant supply line 130 and gas distributor 132. In some embodiments, the gaseous oxygen precursor may comprise at least one of ozone (O₃), or molecular oxygen (O₂).

In some embodiments of the disclosure, the exemplary selective deposition device 11 may optionally further comprise a plasma generator 146. The plasma generator 146 may be constructed and arranged to generate a plasma from the gaseous oxygen precursor thereby providing one or more of atomic oxygen, oxygen ions, oxygen radicals, and excited species of oxygen to the reaction chamber 12 whereby the oxygen based plasma produced by the plasma generator 146 may react with the layer 106 disposed over substrate 15.

In some embodiments, each step in the program sequence may be followed by a purge cycle to remove excess precursor and byproducts from the reaction chamber by exhausting the reaction chamber 12 utilizing vacuum pump 138 and optionally flowing a purge gas from source vessel 116. In some embodiments, the program sequence of providing the oxygen precursor followed by the vapor of the first precursor may be repeated one or more times. In some embodiments, each step in the program sequence may be followed by a purge cycle to remove excess precursor and byproducts from the reaction chamber by exhausting the reaction chamber 12 utilizing the vacuum pump 138 and optionally flowing a purge gas from source vessel 116.

In some embodiments of the disclosure, the program in the memory 144 is programmed to execute selective deposition on or in the layer 106 when run on the sequence controller 142 by: activating the precursor distribution system and the removal system to provide the first precursor, subsequently the reactant, subsequently the second precursor, and subsequently the reactant.

In some embodiments of the disclosure, the program in memory 144 may be programmed to execute selective deposition on or in the layer 106 when run on the sequence controller 142 by: activating the precursor distribution system and removal system 14 to repeat providing the first precursor, subsequently the reactant, subsequently the second precursor, and subsequently the reactant multiple times.

In some embodiments of the disclosure, the program in memory 144 may be programmed to execute selective deposition on or in the layer 106 when run on the sequence controller 142 by: activating the precursor distribution system and the removal system to remove the precursors and/or reactants from the reaction chamber in between each step of providing the first precursor, subsequently the reactant, subsequently the second precursor, and subsequently the reactant.

In some embodiments of the disclosure, the program in memory 144 may be programmed to execute selective deposition on or in the layer 106 when run on the sequence controller 142 by: activating the precursor distribution system and the removal system to provide the first precursor, subsequently provide the second precursor, and subsequently provide the reactant. In some embodiments the program sequence of providing the first precursor, subsequently providing the second precursor, and subsequently providing the reactant may be repeated one or more times. In some embodiments each step in the program sequence may be followed by a purge cycle to remove excess precursor and byproducts from the reaction chamber by exhausting the reaction chamber 12 utilizing vacuum pump 138 and optionally flowing a purge gas from source vessel 116.

In some embodiments of the disclosure, the program in memory 144 may be programmed to selective deposition on or in the layer 106 when run on the sequence controller 142 by: activating the precursor distribution system and the removal system to provide the second precursor, subsequently provide the first precursor, and subsequently provide the reactant. In some embodiments the program sequence of providing the second precursor, subsequently providing the first precursor, and subsequently providing the reactant may be repeated one or more times. In some embodiments each step in the program sequence may be followed by a purge cycle to remove excess precursor and byproducts from the reaction chamber by exhausting the reaction chamber 12 utilizing vacuum pump 138 and optionally flowing a purge gas from source vessel 116.

In some embodiments of the disclosure, the program in memory 144 may be programmed to execute selective deposition on or in the layer 106 when run on the sequence controller 142 by: activating the precursor distribution system and the removal system to provide the first precursor, subsequently provide the reactant, and subsequently provide the second precursor. In some embodiments the program sequence of providing the first precursor, subsequently providing the reactant, and subsequently providing the second precursor may be repeated one or more times. In some embodiments each step in the program sequence may be followed by a purge cycle to remove excess precursor and byproducts from the reaction chamber by exhausting the reaction chamber 12 utilizing vacuum pump 138 and optionally flowing a purge gas from source vessel 116.

In some embodiments of the disclosure, the program in memory 144 may be programmed to selective deposit on or in the layer 106 when run on the sequence controller 142 by: activating the precursor distribution system and the removal system to provide the reactant, subsequently provide the first precursor, subsequently provide the second precursor, and subsequently provide the reactant. In some embodiments the program sequence of providing the reactant, subsequently providing the first precursor, subsequently providing the second precursor, and subsequently providing the reactant may be repeated one or more times. In some embodiments each step in the program sequence may be followed by a purge cycle to remove excess precursor and byproducts from the reaction chamber by exhausting the reaction chamber 12 utilizing vacuum pump 138 and optionally flowing a purge gas from source vessel 116.

In some embodiments of the disclosure, the program in memory 144 may be programmed to execute selective deposition on or in the layer 106 when run on the sequence controller 142 by: activating the precursor distribution system and the removal system to provide the reactant, subsequently provide the first precursor, subsequently provide the reactant, and subsequently provide the second precursor. In some embodiments the program sequence of providing the reactant, subsequently providing the first precursor, subsequently providing the reactant, and subsequently providing the second precursor may be repeated one or more times. In some embodiments each step in the program sequence may be followed by a purge cycle to remove excess precursor and byproducts from the reaction chamber by exhausting the reaction chamber 12 utilizing vacuum pump 138 and optionally flowing a purge gas from source vessel 116.

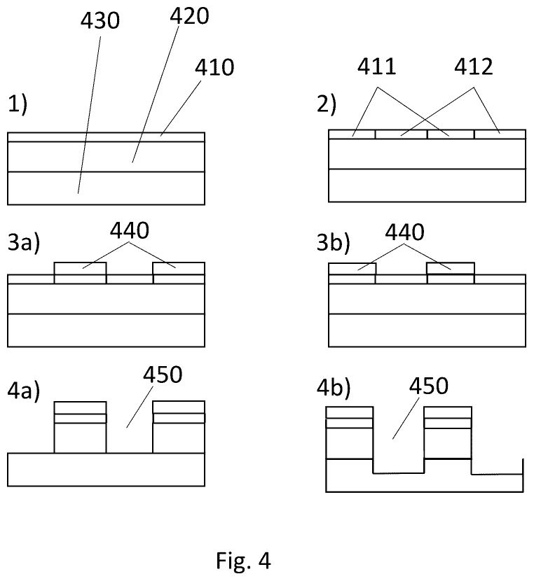

FIG. 4 illustrates a resistless patterning method according to an embodiment of the present disclosure. Panel 1) shows a radiation modifiable layer (410) that is deposited on a substrate (430). As illustrated, an optional underlayer (420) may be provided between the substrate (430) and the radiation modifiable layer (410). In some embodiments, the radiation modifiable layer (410) may consist of a surface of the underlayer (420). It shall be understood that in other embodiments, the radiation modifiable layer (410) may be deposited directly on the substrate, thus obviating the need for an underlayer (420). Panel 2) shows how the radiation modifiable layer (410) may be exposed to extreme ultraviolet (EUV) radiation, thereby creating a plurality of radiation-modified layer portions (411) and a plurality of unmodified layer portions (412). A sacrificial masking layer may then be selectively deposited, either on the radiation-modified layer portions (411) as shown in panel 3b), or on the unmodified layer portions (412) as shown in panel 3a). A subsequent etch step results in the formation of recesses (450), as shown in panels 4a and 4b. In particular, panel 4b shows how recesses (450) are etched underneath the unmodified layer portions (412) when the sacrificial masking layer (440) has been deposited on the radiation-modified layer portions (411). Panel 4a shows how recesses (450) are etched underneath the radiation-modified layer portions (411) when the sacrificial masking layer (440) is deposited on the unmodified layer portions (412). Optionally, the sacrificial masking layer deposition step and the etching step may be performed in one and the same reaction chamber. Optionally, any sacrificial masking layer removal step may be performed in the same reaction chamber as well.

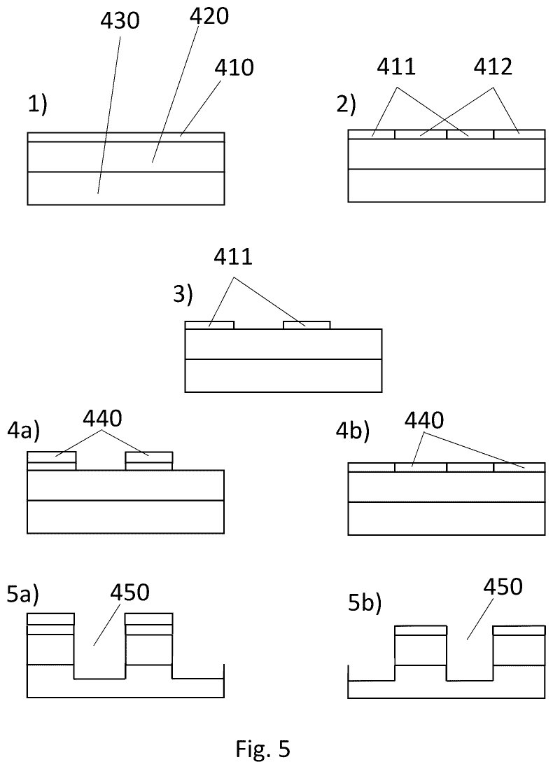

FIG. 5 illustrates a resistless patterning method according to an embodiment of the present disclosure. Panel 1) shows a radiation modifiable layer (410) that is deposited on a substrate (430). The radiation modifiable layer (410) may comprise an organic compound comprising C, N, H and/or O, and may be locally modified by means of photons such as extreme ultraviolet (EUV) photons. This may result in a local change of etch rate towards wet or dry etch processes.

As illustrated, an optional underlayer (420) may be provided between the substrate (430) and the radiation modifiable layer (410). In some embodiments, the radiation modifiable layer (410) may consist of a surface of the underlayer (420). It shall be understood that in other embodiments, the radiation modifiable layer (410) may be deposited directly on the substrate, thus obviating the need for an underlayer (420). Panel 2) shows how the radiation modifiable layer (410) may be exposed to extreme ultraviolet (EUV) radiation, thereby creating a plurality of radiation-modified layer portions (411) and a plurality of unmodified layer portions (412). Panel 3) shows how the unmodified layer portions (412) are removed in a layer removal step, whereas the radiation modified layer portions (411) remain in place. In alternative embodiments (not shown), the unmodified layer portions are unaffected by the layer removal step and thus remain in place, whereas the radiation modified layer portions (411) are removed during the layer removal step.

After the etch step of panel 3), a sacrificial masking layer may be selectively deposited. The sacrificial masking layer may, for example, be deposited on the radiation-modified layer portions (411) as shown in panel 4a), or on the exposed underlayer as shown in panel 4b). In case no underlayer is present, the sacrificial masking layer may be directly deposited on the substrate (430) (embodiment not shown). When the radiation modified layer portions are removed and the unmodified layer portions remain in place during the layer removal step, the sacrificial masking layer may be deposited on the unmodified layer portions (embodiment not shown).

Sacrificial masking layer deposition may then be followed by an etch step which results in the formation of recesses (450) in areas in which no sacrificial masking layer has been deposited, as shown e.g. in panels 5a and 5b. In particular, panel 5a shows how recesses (450) are etched at the positions of the unmodified layer portions (412) when the sacrificial masking layer (440) has been deposited on the radiation-modified layer portions (411). Panel 5b shows how recesses (450) are etched at the positions of the radiation-modified layer portions (411) when the sacrificial masking layer (440) has been deposited on the unmodified layer portions (412). Of course, the same principles apply in other embodiments: areas where no sacrificial masking layer has been deposited are etched during the etching step, and areas where sacrificial masking layer has been deposited are not, or not substantially, etched during the etching step. If desired, the sacrificial masking layer may be removed after the etching step. Optionally, the sacrificial masking layer deposition step and the etching step may be performed in one and the same reaction chamber. Optionally, any sacrificial masking layer removal step may be performed in the same reaction chamber as well.

A suitable radiation modifiable layer (410) includes an amorphous carbon layer, for example an amorphous carbon layer deposited by means of plasma-enhanced atomic layer deposition (PEALD) or by means of plasma-enhanced chemical vapor deposition (PECVD). The amorphous carbon layer may comprise sp2 and sp3 carbon. In other words, the amorphous carbon layer may comprise C═C, C═C, and C—H bonds. In addition, the amorphous carbon may contain C—N and/or C—O bonds. When areas in the amorphous carbon layer are exposed to EUV light, C═C, C—H, C—N, and/or C—O bonds may be broken. Without the present invention being bound to any particular theory or mode of operation, it is believed that the resulting damage may render the exposed amorphous carbon layer portions selectively etchable by H radicals at low temperatures, e.g. at temperatures below 100° C., or at temperatures below 90° C., or at temperatures below 80° C., or at temperatures below 70° C., or at temperatures below 60° C., or at temperatures below 50° C., or at temperatures below 40° C. The H radicals may be produced, for example, in a remote plasma tool. It is believed that the unexposed amorphous carbon layer portions are not etched by H radicals at these low temperatures because the unexposed amorphous carbon layer portions have not been damaged by EUV exposure, and because C═C bonds in the amorphous carbon are not substantially etched by the H radicals. In addition, and without the invention being bound by any specific theory or mode of operation, it is believed that the H radicals may hydrogenate the surface of the amorphous carbon layer, thus resulting in the formation of CH₃ terminal groups on the surface. Thus, it is believed areas with CH₃-terminated amorphous carbon may thus be formed, which can be used as a blocking or active layer during the deposition of a sacrificial masking layer.

One example of a sacrificial masking layer which can be selectively deposited on CH₃-terminated amorphous carbon is RuO₂., e.g. starting by means of a precursor comprising RuO₄ in an organic solvent. Compositions comprising RuO₄ in organic solvents are commercially available.

Examples of masking layers which can be selectively deposited on the underlayer or substrate, and not on the CH₃-terminated amorphous carbon include atomic layer deposition of TiO (i.e. titanium oxide)ₓ, TiOₓC_{y} (i.e. titanium oxycarbide), or TiN by means of a titanium halide precursor such as TiCl₄; atomic layer deposition of hafnium oxide by means of a hafnium halide precursor such as HfCl₄, and atomic layer deposition of Ruthernium by means of EBECHRu. Underlayers and substrates that these materials can be selectively deposited on versus CH₃-terminated amorphous carbon include metal-based underlayers and silicon-based underlayers and substrates such as monocrystalline silicon, spin-on silicon, and low-k dielectrics. When the masking layer is selected from titanium oxide, titanium nitride and ruthenium, then an adequate underlayer for selective deposition with respect to CH₃-terminated amorphous carbon may comprise SiO2, SiN, and/or SiON. When the masking layer is selected from titanium oxide or titanium nitride, then an adequate underlayer for selective deposition with respect to CH₃-terminated amorphous carbon may comprise ruthenium. When ruthenium is used as a masking layer, then a suitable underlayer for selective deposition with respect to CH₃-terminated amorphous carbon may comprise titanium oxide or titanium nitride. In some embodiments, the aforementioned underlayers may additionally comprise tin, which may reduce the required EUV dose for achieving proper exposure.

The present methods and devices, when used for depositions, etches, and/or other purposes, offer numerous advantages. For example, problems associated with resist collapse may be avoided. Conversely, prior art techniques employing thick resist lines (e.g. 30 nm thick) may suffer from resist line collapse during the wet development step when adhesion between the resist and an underlayer is not strong enough. In addition, the approaches disclosed herein avoid issues that may arise when using resist comprising a photo-acid generator (PAG) such as PAG segregation and PAG quenching. In addition, when used for etch purposes, the present methods allow selective deposition of a sacrificial masking layer having an excellent etch budget, even while only requiring a very thin underlayer and providing very high resolution, e.g. a resolution of 13 nm, or even a resolution of ca. 8 nm when a high numerical aperture is used.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A substrate processing method to create a sacrificial masking layer comprising:
performing a selective atomic layer deposition (ALD) cycle, the selective ALD cycle comprising:
providing a first precursor selected to react with a reacting portion and not react with a non-reacting portion in a reaction chamber, the reacting portion including one of a modified layer portion and an unmodified layer portion, the non-reacting portion including the other one of the modified layer portion and the unmodified layer portion, wherein the first precursor comprises a material selected from the group consisting of a metal, silicon (Si), and germanium (Ge);
selectively growing at least a portion of the sacrificial masking layer on the reacting portion relative to the non-reacting portion by contacting the reacting portion and the non-reacting portion with the first precursor; and subsequently
purging, by flowing a purge gas through the reaction chamber, an unreacted portion of the first precursor and/or reaction by-products from the reaction chamber to leave the non-reacting portion as an exposed portion of the modified layer portion and the unmodified layer portion.

2. The substrate processing method of claim 1, further comprising contacting the modified layer portion and the unmodified layer portion with a second precursor, wherein the second precursor comprises NH₃ or H₂O.

3. The substrate processing method of claim 1, wherein the first precursor comprises a material selected from the group consisting of TiCl₄, TDMAT, TTIP, and HfCl₄.

4. The substrate processing method of claim 1, further comprising providing a substrate with a radiation modifiable layer to a lithographic projection apparatus for locally modifying the radiation modifiable layer, wherein the radiation modifiable layer has a thickness between 0.1 to 20 nm.

5. The substrate processing method of claim 1, wherein the purging is performed by a precursor distribution and removal system and via the purge gas.

6. The substrate processing method of claim 5, wherein the selective ALD cycle further comprises selectively growing at least a second portion of the sacrificial masking layer by providing a second precursor to the reaction chamber after the unreacted portion of the first precursor is removed from the reaction chamber.

7. The substrate processing method of claim 6, wherein the selective ALD cycle further comprises purging, by flowing the purge gas through the reaction chamber, an unreacted portion of the second precursor and/or reaction by-products from the reaction chamber.

8. A substrate processing method to create a patterned substrate comprising:
creating a sacrificial masking layer according to claim 1;
etching a substrate through the sacrificial masking layer; and
removing the sacrificial masking layer.

9. A substrate processing method to create a patterned substrate comprising:
creating a sacrificial masking layer according to claim 1; and
etching a substrate through the exposed portion of the modified and unmodified layer portions, wherein the sacrificial masking layer protects a non-exposed portion of the modified and unmodified layer from the etching.

10. The substrate processing method of claim 9, wherein recesses are formed in the substrate in response to the etching the substrate through the exposed portion of the modified and unmodified layer portions while the sacrificial masking layer remains.

11. The substrate processing method according to claim 1, further comprising repeating the selective ALD cycle.

12. A substrate processing method to create a sacrificial masking layer comprising:
performing a selective atomic layer deposition (ALD) cycle, wherein the selective ALD cycle comprises:
providing a precursor selected to react more with a reacting portion relative to a less-reacting portion in a reaction chamber, wherein the reacting portion includes one of a modified layer portion and an unmodified layer portion, and the less-reacting portion including the other of the modified layer portion and the unmodified layer portion, the modified layer portion comprising CHₓ groups, with x being an integer from 1 to 3, the unmodified layer portion including OH groups;
selectively growing the sacrificial masking layer on the reacting portion relative to the less-reacting portion by contacting the reacting portion and the less-reacting portion with the precursor; and
purging, by flowing a purge gas through the reaction chamber, an unreacted portion of the precursor and/or reaction by-products from the reaction chamber.

13. The substrate processing method according to claim 12, further comprising repeating the selective ALD cycle.

14. The substrate processing method of claim 12, providing a substrate with a radiation modifiable layer to a lithographic projection apparatus for locally modifying the radiation modifiable layer, wherein the radiation modifiable layer has a thickness between 0.1 to 20 nm.

15. The substrate processing method of claim 12, wherein the purging is performed by a precursor distribution and removal system and via the purge gas.

16. The substrate processing method of claim 15, wherein the selective ALD cycle further comprises selectively growing at least a second portion of the sacrificial masking layer by providing a second precursor to the reaction chamber after the unreacted portion of the precursor is removed from the reaction chamber.

17. The substrate processing method of claim 16, wherein the selective ALD cycle further comprises purging, by flowing the purge gas through the reaction chamber, an unreacted portion of the second precursor and/or reaction by-products from the reaction chamber.

18. A substrate processing method to create a patterned substrate comprising:
creating a sacrificial masking layer according to claim 17;
etching a substrate through the sacrificial masking layer; and
removing the sacrificial masking layer.

19. A substrate processing method to create a patterned substrate comprising:
creating a sacrificial masking layer according to claim 12; and
etching a substrate through an exposed portion of the modified layer portion and the unmodified layer portion, wherein the sacrificial masking layer protects a non-exposed portion of the modified and unmodified layer from the etching.

20. The substrate processing method of claim 19, wherein recesses are formed in the substrate in response to the etching the substrate through the exposed portion of the modified and unmodified layer portions while the sacrificial masking layer remains.
